(19) United States
(12) Patent Application Publication
(10) Pub. No.: US 2026/0360394 A1
(43) Pub. Date: Nov. 12, 2026

(54) MEMORY DEVICE WITH A FLY WORD LINE

(71) Applicant: Taiwan Semiconductor Manufacturing Company, Ltd., Hsinchu (TW)

(72) Inventors: Sungchieh LIN, Hsinchu (TW); Kuoyuan HSU, San Jose, CA (US)

(21) Appl. No.: 19/351,065

(22) Filed: Oct. 6, 2025

Related U.S. Application Data
(60) Provisional application No. 63/804,408, filed on May 12, 2025.

(51) Int. Cl. G11C 5/06; G11C 11/417; H10B 10/00

(52) U.S. Cl. CPC G11C 5/063; G11C 11/417; H10B 10/12

(57) ABSTRACT

A memory device with a Fly Word Line (FWL) is provided. The memory device includes an array having a plurality of rows and a plurality of columns. A row of the plurality of rows includes a first plurality of memory cells. A first portion of the first plurality of memory cells are connected to a first segment Word Line (WL) and a second portion of the first plurality of memory cells are connected to a second segment WL. The array further includes a FWL extending above the first segment WL in a first direction. The FWL is spaced apart from the first segment WL in a second direction perpendicular to the first direction. The FWL is coupled to the second segment WL.

### CROSS-REFERENCE TO RELATED APPLICATION

This application claims priority to and the benefit of U.S. Provisional Application No. 63/804,408, filed May 12, 2025, which is incorporated herein by reference in its entirety for all purposes.

### BACKGROUND

A semiconductor memory device is an electronic data storage device implemented on a semiconductor-based integrated circuit. A semiconductor memory device has various types, and has faster access times than other data storage technologies. For example, a byte of data can often be written to or read from a semiconductor memory device within a few nanoseconds, while access times for rotating storage, such as hard disks, is in the range of milliseconds. For these reasons, among others, the semiconductor memory device is used as a primary storage mechanism for computers to hold data that the computers are currently working on, among other uses.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device, in accordance with some embodiments.

FIG. 2A illustrates a schematic diagram of a memory cell, in accordance with some embodiments.

FIG. 2B illustrates a schematic diagram of another memory cell, in accordance with some embodiments.

FIG. 3 illustrates a fly word line of a memory device in accordance with some embodiments.

FIG. 4 illustrates an example layout of the row of FIG. 3 in accordance with some embodiments.

FIG. 5 illustrates a delay time analysis diagram of the row of FIG. 3, in accordance with some embodiments.

FIG. 6 is a flow diagram of a method for determining a cut location of a word line in accordance with some embodiments.

FIG. 7A is a flow diagram of a first method for forming a memory device with a fly word line in accordance with some embodiments.

FIG. 7B is a flow diagram of a second method for forming a memory device with a fly word line in accordance with some embodiments.

FIG. 8 is a block diagram of a layout system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Static Random Access Memory (SRAM) is a type of a semiconductor memory device that stores data in the form of bits using bistable circuitry without the need for refreshing. A SRAM cell may be referred to as a bit cell because it stores a bit of information. A SRAM cell is bistable, meaning it can maintain its state indefinitely as long as an adequate power is supplied. A SRAM can operate at a higher speed and lower power dissipation, so computer cache memories use SRAMs. Other applications include embedded memories and networking equipment memories. There are several types of SRAM cells (e.g., 6-transistor (6T) SRAM, dual port 8-transistor (8T) SRAM, etc.).

A memory array generally includes multiple bit cells arranged in rows and columns. Each bit cell in a memory array may include connections to a power supply voltage and to a reference voltage. Bit Lines (BLs) may be used for accessing a bit cell with a Word Line (WL) controlling connections to the BLs. A WL may be coupled to a corresponding set of the bit cells that are arranged in a row of a memory array with different WLs provided for respective rows, and a BL may be coupled to a corresponding set of the bit cells that are arranged in a column of a memory array with different BLs provided for respective columns. Typically, the bit lines extend in one direction (parallel to a first axis) and the word lines extend in a second direction (parallel to a second axis) perpendicular to the first direction.

In some examples, each memory cell of an array uses six transistors, for example, connected between an upper reference potential and a lower reference potential (typically ground) such that one of two storage nodes can be occupied by the information to be stored, with the complementary information stored at the other storage node. Each bit in the SRAM cell is stored on four of the transistors, which form two cross-coupled inverters. The other two transistors are connected to the memory cell word line to control access (i.e. “access transistors”) to the memory cell during read and write operations by selectively connecting the cell to its bit lines. In a read operation, for example, the BLs are pre-charged to a predefined threshold voltage. When the WL is enabled, a sense amplifier connected to the BLs senses and outputs stored information.

Another SRAM memory device uses eight transistors (8T), in which separate read/write BLs and WLs are used. The access transistors mentioned above have their gate terminals connected to write WLs and as such are referred to herein as “write access transistors,” while an additional two transistors function as read access transistors. The write access transistors control the write operation in the 8T SRAM cell. These transistors are typically NMOS transistors, with one connected to the BL and the other connected to the complementary bit line (BLB). The gates of these access transistors are connected to the WL, which controls the access to the cell during write and read operations. When the WL is activated, the access transistors enable writing data into the cell by allowing the bit-lines to drive the stored data values.

The read access transistors control the read operation in the 8T SRAM cell. These transistors are also typically NMOS transistors, with a first read access transistor one having its gate terminal connected to a read WL (RWL), one source/drain terminal connected a read BL (RBL), and the other source/drain terminal connected to a source/drain terminal of the second read access transistor. The second read access transistor has its gate terminal connected to the cross-coupled inverters, and its other source/drain terminal connected to VSS.

As noted above, a pair of cross-coupled inverters are formed by four transistors. These transistors are typically implemented as Complementary Metal-oxide-Semiconductor (CMOS) technology, where each inverter consists of one p-type Metal-Oxide-Semiconductor (PMOS) and one n-type metal-oxide-semiconductor (NMOS) transistor. The gates of the PMOS and NMOS transistors are connected to each other, creating a feedback loop. This cross-coupled structure allows the cell to store a single bit of data (0 or 1) by latching the complementary values on the bit-lines.

As memory devices get larger, longer WLs may be needed. Longer WLs may degrade the speed of the memory device. For example, long WLs with one metal layer or double metal layers can develop large RC, which may limit the access time speed. Therefore, embodiments of the disclosure provide a Fly WL (FWL) in a metal layer that is different and separate from the metal layer forming the WL. A WL for a row of the array is segmented into a first segment WL and a second segment WL. A first portion of the first plurality of memory cells of the row are connected to the first segment WL and a second portion of the first plurality of memory cells of the row are connected to the second segment WL. The FWL extends above the first segment WL in a first direction. The FWL is spaced apart from the first segment WL in a second direction perpendicular to the first direction. The FWL is coupled to the second segment WL. As discussed in greater detail in the following sections of the disclosure, the WL for a row is segmented such that a time delay at a distal end of the first segment WL is substantially same as a second time delay at a distal end of the second segment WL from a WL driver.

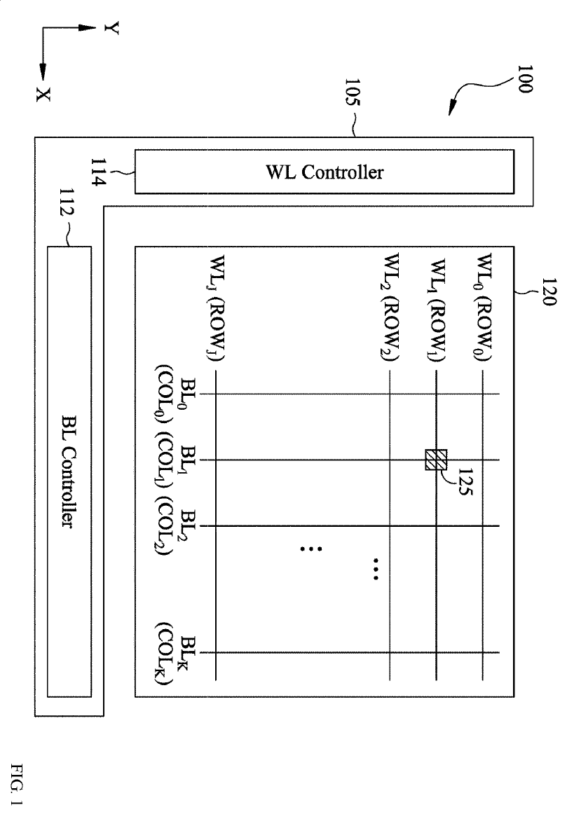

FIG. 1 illustrates a block diagram of a memory device 100, in accordance with some embodiments. As shown, memory device 100 includes a controller 105 and an array 120. Array 120 may include a plurality of storage circuits or memory cells 125. Each memory cells 125 may be coupled to a corresponding WL and a corresponding BL (or a pair of BLs). Controller 105 may write data to or read data from array 120 according to electrical signals through the WLs and BLs.

Array 120 includes a plurality of memory cells 125 arranged in a metric of a plurality of rows and a plurality of columns. Array 120 further includes a plurality of WLs, that is, WL₀, WL₁. . . WL_{J}, each extending in a first direction (e.g., the X-direction) and a plurality of BLs, that is, BL₀, BL₁. . . BL_{K}, each extending in a second direction (e.g., the Y-direction). Each of the plurality of WLs (that is, WL₀to WL_{J}) are associated with a row of a plurality of rows, ROW₀ to ROW_{J}. Similarly, each of the plurality of BLs (that is, BL0 to BLK) is associated with a column of the plurality of columns, COL₀to COL_{K}. The WLs and the BLs may each be implemented as one or more metal or conductive tracks disposed in respective metallization layers. Each of the plurality of memory cells 125 of array 120 is coupled to a corresponding WL and a corresponding BL, and can be operated according to voltages or currents through the corresponding WL and the corresponding BL.

In some examples, each BL may include a BL, and a BLB (complementary to the BL) coupled to a first plurality of memory cells 125 disposed along the second direction (e.g., Y-direction), or along a corresponding one of the columns, COL₀to COL_{K}. The BL and BLB may receive or provide differential signals. In some examples, each memory cell 125 is a SRAM cell. However, memory cell 125 may be a Dynamic Random Access Memory (DRAM) cell, a Resistive Random Access Memory (RRAM) cell, a Magnetoresistive Random Access Memory (MRAM) cell, etc. In some examples, array 120 may include additional lines, for example, select lines, reference lines, reference control lines, power rails, etc.

Controller 105 is a hardware component that controls operations array 120. Controller 105 includes a BL controller 112 and a WL controller 114. BL controller 112 and WL controller 114 may be embodied as logic circuits, analog circuits, or a combination of them. In one example, WL controller 114 is a circuit that provides a voltage or current through one or more WLs of array 120, and BL controller 112 is a circuit that provides or senses a voltage or current through one or more BLs of array 120. BL controller 112 may be coupled to BLs of array 120, and WL controller 114 may be coupled to WLs of array 120. In some examples, WL controller 114 may also be referred to as a WL driver and BL controller 112 may be referred to as a pre-charge driver. In some examples, controller 105 may include more, fewer, or different components than shown in FIG. 1.

For example, controller 105 can include a timing controller configured to generate control signals to coordinate operations of BL controller 112 and WL controller 114. In one approach, to write data to a selected memory cell 125, the timing controller may cause WL controller 114 to apply a voltage or current to selected memory cell 125 through a WL coupled to selected memory cell 125 and cause BL controller 112 to apply a voltage or current corresponding to data to be stored to selected memory cell 125 through a BL coupled to selected memory cell 125. In another approach, to read data from a selected memory cell 125, the timing controller may cause WL controller 114 to apply a voltage or current to selected memory cell 125 through a WL coupled to selected memory cell 125 and cause BL controller 112 to sense a voltage or current corresponding to data stored by selected memory cell 125 through a BL coupled to selected memory cell 125.

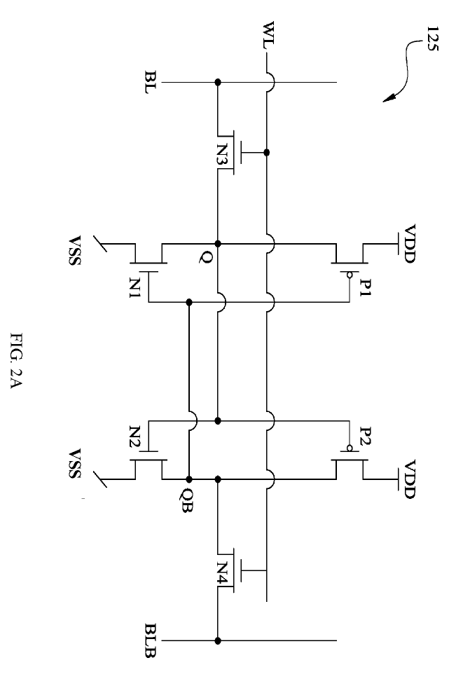

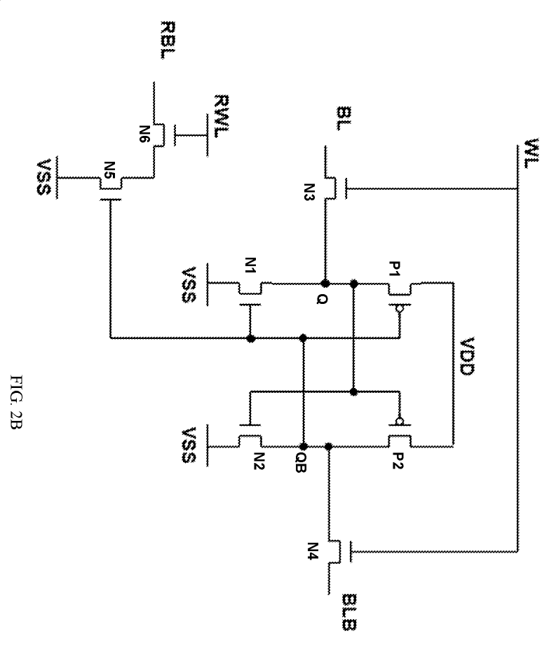

FIG. 2A illustrates a schematic diagram of memory cell 125 that is implemented, for example, as a 6T SRAM cell. As shown in FIG. 2, memory cell 125 includes NMOS transistors N₁, N₂, N₃, N₄and PMOS transistors P₁, P₂. A gate of each of the transistors N₃, N4 are coupled to a WL. A drain/source of the transistor N₃ is coupled to a BL, and a source/drain of the transistor N₃ is coupled to a node Q. A drain/source of the transistor N₄ is coupled to a BLB, and a source/drain of the transistor N₄is coupled to a node QB. The node QB is complementary to the node Q. The transistors N₃, N₄operate as electrical switches and allow the BL to electrically couple to or decouple from the node Q and allow the BLB to electrically couple to or decouple from the node QB based on a voltage applied to the WL. For example, based on a supply voltage VDD corresponding to a high state (or logic value ‘1’) applied to the WL, the transistor N₃is enabled to electrically couple the BL to the nod Q and the transistor N₄is enabled to electrically couple the BLB to the node QB. In another example, based on a ground voltage VSS corresponding to a low state (or logic value ‘0’) applied to the WL, the transistor N₃is disabled to electrically decouple the BL from the node Q and the transistor N₄is disabled to electrically decouple the BLB from the node QB.

The transistor N₁ includes a source/drain coupled to a first supply voltage rail supplying the ground voltage VSS, a gate coupled to the node QB, and a drain/source coupled to the node Q. The transistor P₁ includes a source/drain coupled to a second supply voltage rail supplying the supply voltage VDD, a gate coupled to the node QB, and a drain/source coupled to the node Q. The transistor N₂includes a source/drain coupled to the first supply voltage rail supplying the ground voltage VSS, a gate coupled to the node Q, and a drain/source coupled to the node QB. The transistor P₂ includes a source/drain coupled to the second supply voltage rail supplying the supply voltage VDD, a gate coupled to the node Q, and a drain/source coupled to the node QB. The transistor N₁ and the transistor P₁ operate as a first inverter, and the transistor N₂and the transistor P₂operate as a second inverter, cross-coupled to each other. The cross-coupled inverters may sense and amplify a difference in voltages at the nodes Q, QB. When writing data, the cross-coupled inverters may sense voltages at the nodes Q, QB provided through the transistors N₃, N₄ and amplify a difference in voltages at the BL and BLB. For example, the cross-coupled inverters sense a voltage 0.5 V at the node Q and a voltage 0.4V at the node QB, and amplify a difference in the voltages at the nodes Q, QB through a positive feedback (or a regenerative feedback) such that the voltage at the node Q becomes the supply voltage VDD (e.g., 1V) and the voltage at the node QB becomes the ground voltage VSS (e.g. 0V). The amplified voltages at the nodes Q, QB may be provided to the BL, BLB through the transistors N₃, N₄, respectively for reading.

FIG. 2B illustrates a schematic diagram of another memory cell 130 that is implemented, for example, as an 8T SRAM cell. As shown in FIG. 2B, memory cell 130 includes NMOS transistors N₁, N₂, N₃, N₄,N₅, N₆ and PMOS transistors P₁, P₂. Thus, memory cell 130 includes two additional NMOS transistors compared to the 6T memory cell 125 of FIG. 2A. The NMOS transistors N₁, N₂, N₃, N₄ and PMOS transistors P₁, P₂are connected in a same fashion as memory cell 125 of FIG. 2A. That is, a gate of each of the transistors N₃, N4 are coupled to a WL. A drain/source of the transistor N₃is coupled to a BL, and a source/drain of the transistor N₃is coupled to a node Q. A drain/source of the transistor N₄is coupled to a BLB, and a source/drain of the transistor N₄is coupled to a node QB.

The transistor N₁ includes a source/drain coupled to a first supply voltage rail supplying the ground voltage VSS, a gate coupled to the node QB, and a drain/source coupled to the node Q. The transistor P₁ includes a source/drain coupled to a second supply voltage rail supplying the supply voltage VDD, a gate coupled to the node QB, and a drain/source coupled to the node Q. The transistor N₂includes a source/drain coupled to the first supply voltage rail supplying the ground voltage VSS, a gate coupled to the node Q, and a drain/source coupled to the node QB. The transistor P₂ includes a source/drain coupled to the second supply voltage rail supplying the supply voltage VDD, a gate coupled to the node Q, and a drain/source coupled to the node QB. The transistor N₁and the transistor P₁ operate as a first inverter, and the transistor N₂and the transistor P₂operate as a second inverter, cross-coupled to each other.

The transistor N₅ includes a source/drain coupled to the first supply voltage rail supplying the ground voltage VSS, a gate coupled to the node QB, and a drain/source coupled to a source/drain of the transistor N₆. A drain/source of the transistor N₆ is connected to a read BL and a gate of the transistor N₆ is coupled to a read WL. The read BL and the read WL may be used to perform a read operation on memory cell 130 while the BL and the WL may be used to perform a write operation on memory cell 130. Thus, transistors N₅ and N₆ provide a separate read port or an independent read path for memory cell 130. This improves read stability as the read operation does not disturb the read data.

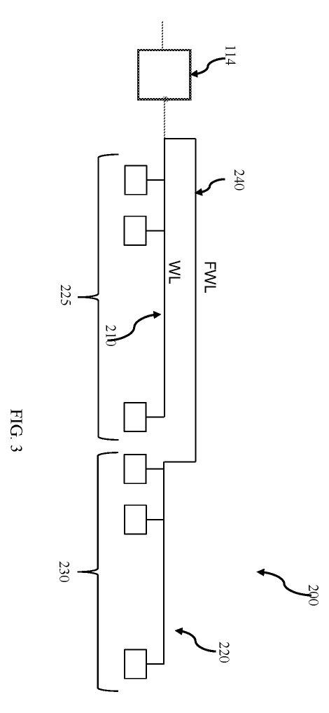

FIG. 3 illustrates an example row 200 with a FWL of array 120 of memory device 100. As discussed above, row 200 of array 120 may include a first plurality of memory cells. As shown in FIG. 3, a WL for row 200 is segmented into a first segment WL 210 and a second segment WL 220. In other words, a WL of row 200 is divided or partitioned into two segments - referred to herein as first segment WL 210 and second segment WL 220. In some other examples, a WL of row 200 is formed in two segments, that is, first segment WL 210 and second segment WL 220. In one example, second segment WL 220 is also referred to as a distal segment as it is further away from WL controller 114 as compared to first segment WL 210. In examples, first segment WL 210 and second segment WL 220 are not electrically connected to each other.

A first portion 225 of the first plurality of memory cells of row 200 are connected to or remain connected to first segment WL 210 and a second portion 230 of the first plurality of memory cells of row 200 are connected to or remain connected to second segment WL 220. In some examples, a number of memory cells in first portion 225 may greater than that of second portion 230. In some other examples, a number of memory cells in first portion 225 may same as that of second portion 230. First segment WL 210 is connected to WL controller 114 at a first end.

As shown in FIG. 3, row 200 further includes a FWL 240. FWL 240 extends parallel to first segment WL 210. A first end of FWL 240 is connected to WL controller 114 and a second end of FWL 240 is connected to a first end of second segment WL 220. That is, FWL 240 is connected to a distal segment of the WL. Thus, second segment WL 220 is connected to WL controller 114 through FWL 240.

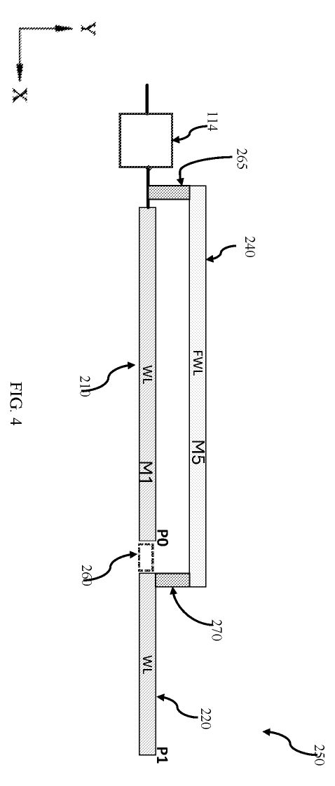

FIG. 4 illustrates an example layout 250 of row 200 of FIG. 3. As shown in example layout 250 of FIG. 4, both first segment WL 210 and second segment WL 220 are formed in the same metal layer, for example, a first metal layer. In some examples, the first metal layer is a metal layer one (that is, M1). In addition, and as shown in example layout 250, each of first segment WL 210 and second segment W are arranged along or extend in the first direction. First segment WL 210 is separated from second segment WL by a cut location 260. In examples, and as discussed above, a WL for row 200 is segmented into first segment WL 210 and second segment WL 220 by removing WL metal from cut location 260. Thus, each of first segment WL 210 and second segment WL 220 may be of substantially same thickness and same material. In one example and discussed in a greater detail in the following sections of the disclosure, cut location 260 is determined based on a delay time analysis.

As shown in example layout 250, FWL 240 also extends in the first direction above or over first segment WL 210. FWL 240 is connected to WL controller 114 at a first end through a first via 265 and to second segment WL 220 at a second end through a second via 270. FWL 240 is formed in a different metal layer than that of first segment WL 210 and second segment WL220, and as such, is separated from the first segment WL 210 in the second direction perpendicular to the first direction. For example, FWL 240 is formed in a second metal layer that is different from the first metal layer. In some examples, the second metal layer can be metal layer five (that is, M5). Conductive vertical interconnects (Vias) connect FWL 240 between the first and second metal layers. For example, FWL 240 is connected to WL controller 114 at a first end through first via 265 and to second segment WL 220 at a second end through second via 270.

When viewed in the second direction (e.g. viewed from above in a plan view), FWL 240 overlaps first segment WL 210 in some implementations, though the disclosure is not limited to such an overlapping configuration. In other implementations, FWL 240 does not overlap first segment WL 210 when viewed in the second direction. In other words, FWL 240 may be offset from first segment WL 210 when viewed in the second direction.

In some examples, FWL 240 is longer (i.e. distance in the first direction) than first segment WL 210. In some other examples FWL 240 is longer than both first segment WL 210 and second segment WL 220. In still further examples, first segment WL 210 is longer than second segment WL 220. Since FWL 240 may not be affected by the capacitance of first portion 225 of the first plurality of memory cells, access speed can be faster. In some examples, a thickness of FWL 240 can be same as or different from a thickness of first segment WL 210.

In examples, cut location 260 for a WL to create first segment WL 210 and second segment WL 220 is determined based on a delay time analysis. That is, a location at which FWL 240 is connected to second segment WL 220 is determined to optimize an access time from WL controller 114. For example, a delay time of first segment WL 210 and of second segment WL 220 with FWL 240 is compared to an arrangement in which first portion 225 and second portion 230 of the first plurality of memory cells of a row all connected to a single WL in a conventional manner.

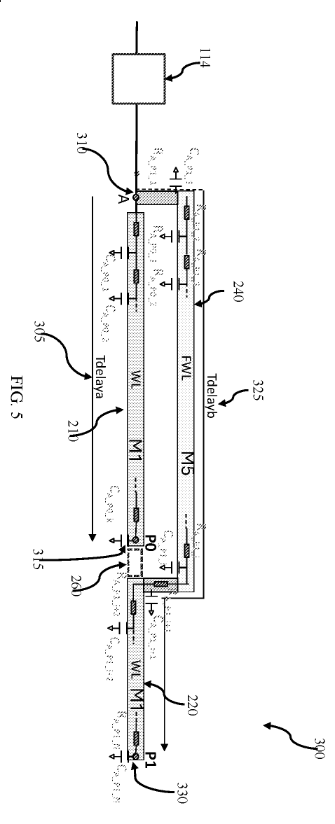

FIG. 5 illustrates a delay time analysis diagram of row 200 of FIG. 3. As shown in FIG. 5, a first delay time, that is, Tdelaya 305 for first segment WL 210 is between first node 310 (that is, node A) and a first end node 315 (that is, node P0). The Tdelaya 305 is provided as:
Tdelaya = ∑ R_{A_P0_k} x C_{A_P0_k}
where: RA_P0_k are the distributed resistances from the node A (that is, first node 310) to the node P0 (that is, first end node 315); CA_P0_k are the distributed capacitances from the node A (that is, first node 310) to the node P0 (that is, first end node 315); and k is an integer number (that is, k = 1, 2, 3, … ). Thus, Tdelaya 305 is determined based on a first distributed resistance value and a first distributed capacitance value associated with the first segment word line. In some examples, first end node 315 is also referred to as a first distal end of first segment WL 210.

In addition, a second delay time, that is, Tdelayb 325 for second segment WL 220 is between first node 310 (that is, node A) and a second end node 330 (that is, node P1). The Tdelayb 325 is provided as:
Tdelayb = ∑ R_{A_P1_n} x C_{A_P1_n}
where: RA_P1_n are the distributed resistances from the node A (that is, first node 310) to the node P1 (that is, second end node 330); CA_P1_n are the distributed capacitances from the node A (that is, first node 310) to the node P1 (that is, second end node 330); and n is an integer (that is, n = 1, 2, 3, …). In some examples, second end node 330 is also referred to as a second distal end of second segment WL 220. Thus, Tdelayb 325 is determined based on: a second distributed resistance value and a second distributed capacitance value associated with the first segment word line, and a third distributed resistance value and a third distributed capacitance value associated with the flying word line.

Cut location 260 is determined where Tdelaya 305 is substantially equal to Tdelayb 325. Further, the relative lengths of first segment WL 210 and second segment WL 220 is varied, and simulations are run to determine delay times at end points of each of first segment WL 210 and second segment WL 220 (that is, Tdelaya 305 and Tdelayb 325). The optimum point is where the delay time of the node P0 (that is, first end node 315) and the node P1 (that is, second end node 330) is the same (that is, Tdelaya 305= Tdelayb 325). That is, a first delay time (that is, Tdelaya 305) at a first distal end (that is, first end node 315 or node P0) of first segment WL 210 is same as a second delay time (that is, Tdelayb 325) at a second distal end (that is, second end node 330 or node P1) of the second segment 220. In some examples, a size of WL controller 114 can be varied to ensure it is sufficient to output the desired signal to memory cells 124 with first segment WL 210, second segment WL 220, and FWL 240 arrangement.

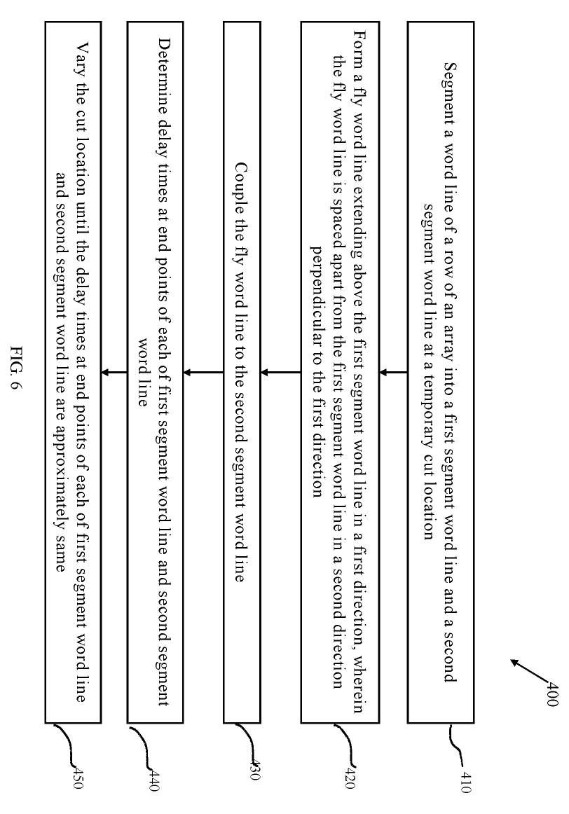

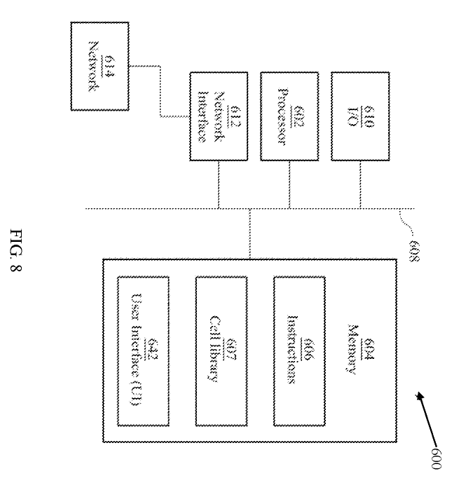

FIG. 6 is a flow diagram illustrating a method 400 for determining cut location 260 in accordance with some embodiments. In some examples, method 400 may be a simulation method to determine cut location 260 for a WL of memory device 100. Method 400 may be performed by a layout system 600 discussed with reference to FIG. 8 of the disclosure. In some examples, method 400 may be stored as instructions on a memory device, which when executed by a processor can cause the processor to perform method 400. Ways to implement the stages of method 400 will be described in greater detail below.

At stage 410 of method 400, a WL of row 200 of an array is segmented into first segment WL 210 and second segment 220 at a temporary cut location. For example, a simulation model of a row (for example, row 200) of memory device 100 may be created. In some examples, the simulation model for entire memory device 100 may be created. As discussed above, row 200 of array 120 includes a first plurality of memory cells, and the WL is connected to the first plurality of memory cells of the row. In the simulation modes, the WL is segmented into first segment WL 210 and second segment 220 by removing a portion of the WL at the temporary cut location. As discussed above, a length of first segment WL 210 is greater than a length of second segment WL 220. In addition, each of first segment WL 210 and the second segment 220 are formed in a first metal layer (for example, metal layer one or a M1 layer) extending in a first direction.

At stage 420 of method 400, FWL 240 is formed extending above first segment WL 210 in the first direction. For example, FWL 240 is formed in the simulation model. As discussed above, FWL 240 is spaced apart from first segment WL 210 in a second direction perpendicular to the first direction. FWL 240 is formed in a second metal layer (for example, metal layer 5 or M5).

At stage 430 of method 400, FWL 240 is coupled to second segment WL 220. For example, FWL 240 is coupled to second segment WL 220 in the simulation model. FWL 240 is coupled to second segment WL 220 through a connection structure that includes one or more vias formed in a vertical direction (that is, a second direction perpendicular to the first direction) between FWL 240 and second segment WL 220.

At stage 440 of method 400, delay times at end points of each of first segment WL 210 and second segment WL 220 are determined. In examples, the delay times are determined by propagating WL signals through each of first segment WL 210 and second segment WL 220 in the simulation model. In some example examples, the delay times are determined based on process discussed with reference to FIG. 5 above.

At stage 440 of method 400, the temporary cut location is varied until the delay times at end points of each of first segment WL 210 and second segment WL 220 are approximately same. For example, based on the delay times determined at stage 440, the temporary cut location may be shifted in the simulation model either the left or to the right of a current cut location to change the delay times. The temporary location where the delay time are approximately same is labeled as the optimum point. This optimal point may be determined as cut location 260.

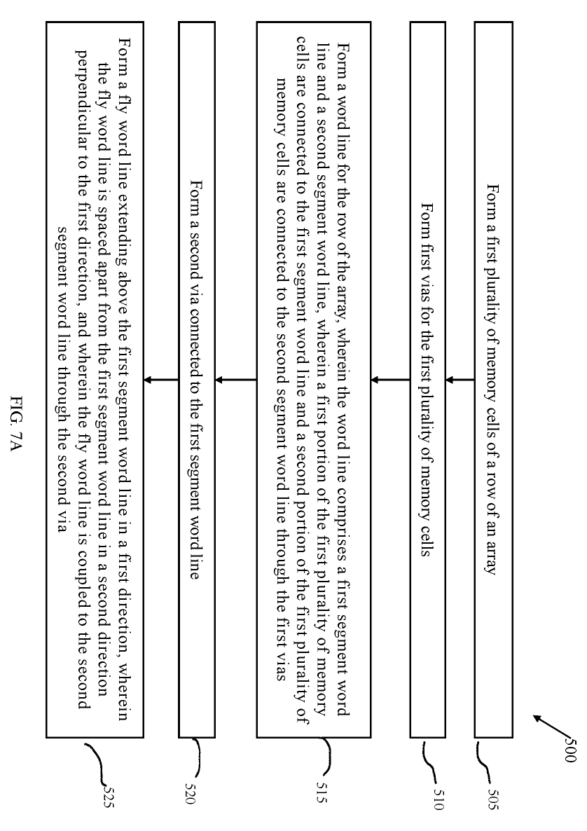

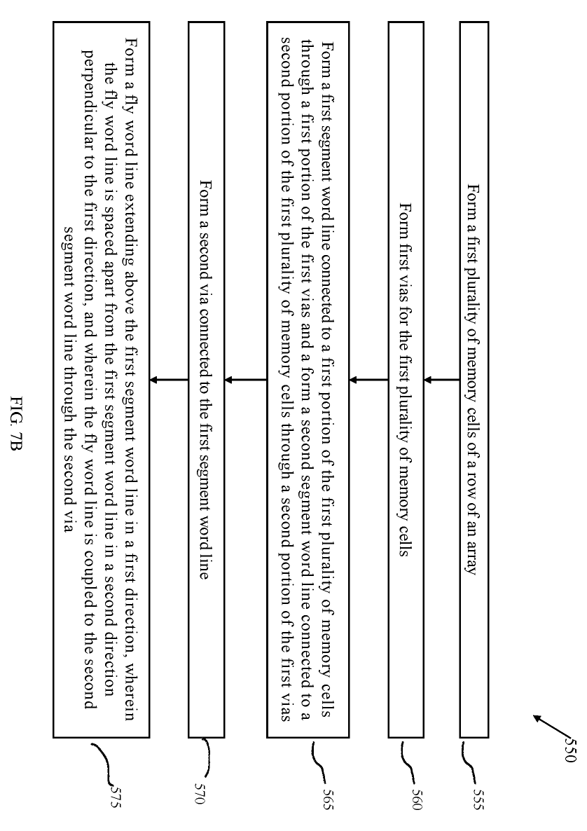

FIG. 7A is a flow diagram illustrating a first method 500 for forming memory device 100 in accordance with some embodiments. Method 500 may be performed by a layout system 600 as discussed with reference to FIG. 8 of the disclosure. In some examples, method 500 may be stored as instructions on a memory device, which when executed by a processor can cause the processor to perform method 500. Ways to implement the stages of method 500 will be described in greater detail below.

At stage 505 of method 500, a first plurality of memory cells of row 200 of memory device 100 are formed.

At stage 510 of method 500, first vias for the first plurality of memory cells of row 200 of memory device 100 are formed. The first vias may be connected to the first plurality of memory cells. For example, a first end of first vias may be connected to the first plurality of memory cells.

At stage 515 of method 500, a WL for the row 200 of the array is. The WL may be formed in a first metal layer and may extend in a first direction. The WL may include first segment WL 210 and second segment WL 220. In some examples, and as discussed above, the WL is segmented into first segment WL 210 and second segment WL 220 by removing a portion of the WL at cut location 260. First portion 225 of the first plurality of memory cells are connected to first segment WL 210 and second portion 230 of the first plurality of memory cells are connected to second segment WL 220 through the first vias. For example, a second end of the first vias are connected to one of first segment WL 210 and second segment WL 220. In some examples, first portion 225 of the first plurality of memory cells may already be connected to the WL before the WL is segmented to form first segment WL 210. Similarly, in some examples, second portion 230 of the first plurality of memory cells may already be connected to the WL before the WL is segmented to form second segment WL 220.

In some examples, a line separation pattern CMD (i.e. “cut-MD pattern”) is used to signify a separation step during the semiconductor fabrication process, by which the WL is segmented into first segment WL 210 and second segment WL 220. The CMD process includes removing a portion from the WL at cut location 260. The removed portion of the WL corresponds to cut location 260. In some embodiments, the portion of the WL that is removed is identified in layout design by a cut feature pattern. In some embodiments, the cut feature pattern identifies cut location 260 of the removed portion.

Such removal processes may include one or more etching processes suitable to remove a portion of the WL. In some embodiments, the etching process includes identifying a portion of the WL that is to be removed and etching the portion of the WL that is to be removed. In some embodiments, a mask is used to specify portions of the WL that are to be cut or removed. In some embodiments the mask is a hard mask, while in other embodiments, the mask is a soft mask. Etching may include, for example, plasma etching, reactive ion etching, chemical etching, dry etching, wet etching, and other suitable processes or combinations thereof. After removal of the portion from the WL, the removed space may be filled by a dielectric material, such as an oxide material, to form cut location 260 that segments the WL into first segment WL 210 and second segment WL 220.

At stage 520 of method 500, a second via connected to first segment WL 210 is formed. In some examples, a first end of the second via may be connected to first segment WL 210.

At stage 525 of method 500, FWL 240 is formed extending above first segment WL 210 in a first direction. As discussed above, FWL 240 is spaced apart from first segment WL 210 in a second direction perpendicular to the first direction. FWL 240 is coupled to second segment WL 220 through the second via. In some examples, a second end of the second via is connected to first segment WL 210. As discussed above, a length of first segment WL 210 is greater than a length of second segment WL 220. In addition, each of first segment WL 210 and the second segment 220 are formed in a first metal layer (for example, metal layer 1 or M1). FWL 240, on the other hand, is formed in a second metal layer (for example, metal layer 5 or M5).

FIG. 7B is a flow diagram illustrating a second method 550 for forming memory device 100 in accordance with some embodiments. Method 550 may be performed by a layout system 600 as discussed with reference to FIG. 8 of the disclosure. In some examples, method 550 may be stored as instructions on a memory device, which when executed by a processor can cause the processor to perform method 550. Ways to implement the stages of method 550 will be described in greater detail below.

At stage 555 of method 550, a first plurality of memory cells of row 200 of memory device 100 are formed.

At stage 560 of method 550, first vias for the first plurality of memory cells of row 200 of memory device 100 are formed. The first vias may be connected to the first plurality of memory cells. For example, a first end of the first vias may be connected to the first plurality of memory cells.

At stage 565 of method 500, a first segment WL 210 connected to first portion 225 of the first plurality of memory cells through a first portion of the first vias is formed and a second segment WL 220 connected to second portion 230 of the first plurality of memory cells through a second portion of the first vias is formed. Each of first segment WL 210 and second segment WL 220 may be formed in a first metal layer and may extend in a first direction. In examples, a second end of the first vias are connected to one of first segment WL 210 and second segment WL 220.

At stage 570 of method 550, a second via connected to the first segment WL 210 is formed. In some examples, a first end of the second via may be connected to first segment WL 210.

At stage 575 of method 550, FWL 240 is formed extending above first segment WL 210 in the first direction. As discussed above, FWL 240 is spaced apart from first segment WL 210 in a second direction perpendicular to the first direction. FWL 240 is coupled to second segment WL 220 through the second via. In some examples, a second end of the second via is connected to first segment WL 210. As discussed above, each of first segment WL 210 and the second segment 220 are formed in a first metal layer (for example, metal layer 1 or M1). FWL 240, on the other hand, is formed in a second metal layer (for example, metal layer 5 or M5).

FIG. 8 is a block diagram of a layout system 600, in accordance with some embodiments. Methods described herein of forming memory device 100 in accordance with one or more embodiments are implementable, for example, using layout system 600. In some examples, layout system 600 is a general-purpose computing device including a hardware processor 602 and a non-transitory, computer-readable storage medium 604. Storage medium 604, amongst other things, is encoded with, i.e., stores, computer program code 606, i.e., a set of executable instructions. Execution of instructions 606 by hardware processor 602 represents (at least in part) an EDA tool which implements a portion or all of method 400 and method 400 for forming memory device 100 as described above with respect to FIGS. 6 and FIG. 7.

Processor 602 is electrically coupled to computer-readable storage medium 604 via a bus 608. Processor 602 is also electrically coupled to an I/O interface 610 by bus 608. A network interface 612 is also electrically connected to processor 602 via bus 608. Network interface 612 is connected to a network 614, so that processor 602 and computer-readable storage medium 604 are capable of connecting to external elements via network 604. Processor 602 is configured to execute computer program code 606 encoded in computer-readable storage medium 604 in order to cause layout diagram generation system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, computer-readable storage medium 604 is an electronic, magnetic, optical, electromagnetic, infrared, and/or a semiconductor system (or apparatus or device). For example, computer-readable storage medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 604 includes a compact disk-read only memory (CD-ROM), a compact disk-read/write (CD-R/W), and/or a digital video disc (DVD).

In one or more embodiments, computer-readable storage medium 604 stores computer program code 606 configured to cause layout diagram generation system 600 (where such execution represents (at least in part) the EDA tool) to be usable for performing a portion or all of the noted processes and/or methods. In one or more embodiments, computer-readable storage medium 604 also stores information which facilitates performing a portion or all of the noted processes and/or methods. In one or more embodiments, computer-readable storage medium 604 stores cell library 607 of cells including such cells as disclosed herein with respect to FIGS. FIGS. 1A-1J, FIGS. 2A-2L, FIGS. 3A-3F, and FIGS. 4A-4F-.

Layout diagram generation system 600 includes I/O interface 610. I/O interface 610 is coupled to external circuitry. I/O interface 610 may include a keyboard, keypad, mouse, trackball, trackpad, touchscreen, and/or cursor direction keys for communicating information and commands to processor 602.

Layout diagram generation system 600 also includes network interface 612 coupled to processor 602. Network interface 612 allows layout generation system 600 to communicate with network 614, to which one or more other computer systems are connected. Network interface 612 may include wireless network interfaces or wired network interfaces.

Layout diagram generation system 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. Layout diagram generation system 600 is configured to receive information related to a UI through I/O interface 610. The information is stored in computer-readable medium 604 as user interface (UI) 642.

In accordance with some embodiments, a memory device comprises: an array comprising a plurality of rows and a plurality of columns, wherein a row of the plurality of rows comprises: a first plurality of memory cells, wherein a first portion of the first plurality of memory cells are connected to a first segment word line and a second portion of the first plurality of memory cells are connected to a second segment word line, and a fly word line extending above the first segment word line in a first direction, wherein the fly word line is spaced apart from the first segment word line in a second direction perpendicular to the first direction, and wherein the fly word line is coupled to the second segment word line.

In accordance with some embodiments, a memory device comprises: an array comprising a plurality of rows and a plurality of columns, wherein a row of the plurality of rows comprises: a word line segmented into a first segment word line and a second segment word line, a first plurality of memory cells, wherein a first portion of the first plurality of memory cells are connected to the first segment word line and a second portion of the first plurality of memory cells are connected to the second segment word line, and a fly word line extending above the first segment word line in a first direction, wherein the fly word line is spaced apart from the first segment word line in a second direction perpendicular to the first direction, and wherein the fly word line is coupled to the second segment word line.

In accordance with example embodiments, a method of forming a memory device, comprises: segmenting a word line of a row of an array into a first segment word line and a second segment word line, wherein the row of the array comprises a first plurality of memory cells; connecting a first portion of the first plurality of memory cells to the first segment word line; connecting a second portion of the first plurality of memory cells to the second segment word line; and forming a fly word line extending above the first segment word line in a first direction, wherein the fly word line is spaced apart from the first segment word line in a second direction perpendicular to the first direction, and wherein the fly word line is coupled to the second segment word line.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device comprising:
an array comprising a plurality of rows and a plurality of columns, wherein a row of the plurality of rows comprises:
a first plurality of memory cells, wherein a first portion of the first plurality of memory cells are connected to a first segment word line and a second portion of the first plurality of memory cells are connected to a second segment word line, and
a fly word line extending above the first segment word line in a first direction, wherein the fly word line is spaced apart from the first segment word line in a second direction perpendicular to the first direction, and wherein the fly word line is coupled to the second segment word line.

2. The memory device of claim 1, wherein each of the first segment word line and the second segment word line are formed in a first metal layer.

3. The memory device of claim 2, wherein the fly word line is formed in a second metal layer, and wherein the second metal layer is different from the first metal layer.

4. The memory device of claim 2, wherein the fly word line is formed in a metal layer five, and wherein each of the first segment word line and the second segment word line are formed in a metal layer one.

5. The memory device of claim 1, wherein word line for the column is segmented at cut location, wherein the cut location is determined based on a first delay time at a first end of the first segment word line and a second delay time at a second end of the second segment word.

6. The memory device of claim 5, wherein the first delay time is determined based on a first distributed resistance value and a first distributed capacitance value associated with the first segment word line, and wherein the second delay time is determined based on:
a second distributed resistance value and a second distributed capacitance value associated with the first segment word line, and
a third distributed resistance value and a third distributed capacitance value associated with the flying word line.

7. The memory device of claim 1, wherein a first delay time at a first end of the first segment word line is equal to a second delay time at a second end of the second segment word.

8. The memory device of claim 1, wherein a number of memory cells in the first portion of the first plurality of memory cells is greater than that of the second portion.

9. A memory device comprising:
an array comprising a plurality of rows and a plurality of columns, wherein a row of the plurality of rows comprises:
a word line segmented into a first segment word line and a second segment word line,
a first plurality of memory cells, wherein a first portion memory cells of the first plurality of memory cells are connected to the first segment word line and a second portion memory cells of the first plurality of memory cells are connected to the second segment word line, and
a fly word line extending above the first segment word line in a first direction, wherein the fly word line is spaced apart from the first segment word line in a second direction perpendicular to the first direction, and wherein the fly word line is coupled to the second segment word line.

10. The memory device of claim 9, wherein a length of the first segment word line is greater than a length of the second segment word line.

11. The memory device of claim 9, wherein a length of the fly word line is greater than a length of the first segment word line.

12. The memory device of claim 9, wherein a length of the fly word line is greater than a length of the second segment word line.

13. The memory device of claim 9, wherein the first plurality of memory cells are Static Random Access Memory (SRAM) cells.

14. The memory device of claim 9, wherein each of the first segment word line and the second segment word line are formed in a first metal layer.

15. The memory device of claim 14, wherein the fly word line is formed in a second metal layer, and wherein the second metal layer is different from the first metal layer.

16. The memory device of claim 14, wherein the fly word line is formed in a metal layer five, and wherein each of the first segment word line and the second segment word line are formed in a metal layer one.

17. The memory device of claim 9, wherein the word line segmented into the first segment word line and the second segment word line at a cut location such that a first delay time at a first distal end of the first segment word line resistance is same as a second delay time at a second distal end of the second segment word line.

18. A method of forming a memory device, the method comprising:
forming a first plurality of memory cells of a row of an array;
forming first vias for the first plurality of memory cells;
forming a word line for the row of the array, wherein the word line comprises a first segment word line and a second segment word line, wherein a first portion of the first plurality of memory cells are connected to the first segment word line and
a second portion of the first plurality of memory cells are connected to the second segment word line through the first vias;
forming a second via connected to the first segment word line; and
forming a fly word line extending above the first segment word line in a first direction, wherein the fly word line is spaced apart from the first segment word line in a second direction perpendicular to the first direction, and wherein the fly word line is coupled to the second segment word line through the second via.

19. The method of claim 18, wherein the word line for the column is segmented at a cut location, wherein the cut location is determined based on a first delay time at a first end of the first segment word line and a second delay time at a second end of the second segment word line, wherein the first delay time is determined based on a first distributed resistance value and a first distributed capacitance value associated with the second segment word line, and wherein the second delay time is determined based on:
a second distributed resistance value and a second distributed capacitance value associated with the first segment word line, and
a third distributed resistance value and a third distributed capacitance value associated with the flying word line.

20. The method of claim 18, wherein each of the first segment word line and the second segment word line are formed in a first metal layer, wherein the fly word line is formed in a second metal layer, and wherein the second metal layer is different from the first metal layer.
